(19) United States
(12) Patent Application Publication
(10) Pub. No.: US 2008/0003745 A1
(43) Pub. Date: Jan. 3, 2008

(54) Method of manufacturing a flash memory device

(75) Inventors: Seong Hwan Myung, Kyeongki-Do (KR); Jung Geun Kim, Seoul (KR); Whee Won Cho, Chungcheongbuk-do (KR); Cheol Mo Jeong, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-Si (KR)

(21) Appl. No.: 11/646,860

(22) Filed: Dec. 28, 2006

(30) Foreign Application Priority Data
Jun. 30, 2006 (KR) KR 2006-60500
Nov. 16, 2006 (KR) KR2006-113185

(51) Int. Cl. H01L 21/336

(52) U.S. Cl. 438/257

(57) ABSTRACT

The present invention relates to a method of manufacturing a flash memory device. The method includes the steps of forming cell gate patterns and select transistor gate patterns on a semiconductor substrate; forming a low dielectric layer on the resultant structure; etching the low dielectric layer, leavinin gaps adjacent the cell gate patterns; and, forming a nitride layer spacer on one side wall of each of the select transistor gate patterns. The resulting flash memory device has an improved rate of change in the threshold voltage and reduces the contact resistance when a self-aligned contact method is subsequently performed.

### BACKGROUND OF THE INVENTION

The present invention relates to a method of manufacturing a flash memory device.

As a flash memory device becomes more highly-integrated, the distance between gate patterns in a cell region of the device becomes narrower. In a flash memory device with a line width of 100 nm or less, an interference phenomenon generally occurs between neighboring floating gates. Due to this interference phenomenon, the threshold voltage of the device is changed, and the device reliability correspondingly decreases. The rate of change of the threshold voltage is largely influenced by the distance between the gate patterns, the presence of insulating material located between the gate patterns, and the like.

### SUMMARY OF THE INVENTION

The present invention addresses the aforementioned problems. An object of the present invention is to provide a method of manufacturing a flash memory device in which the space between gate patterns is filled with a low dielectric material to minimize the interference phenomenon occurring between the gate patterns, thereby improving the cell reliability.

The present invention relates to a method of manufacturing a flash memory device and includes the steps of forming cell gate patterns and select transistor gate patterns on a semiconductor substrate, thereby forming a gate pattern structure; forming a low dielectric layer on the resultant structure; and, etching the low dielectric layer, leaving the low dielectric layer only in gaps adjacent the cell gate patterns.

The method of the present invention further includes forming a buffer oxide layer on the gate pattern structure.

The method of the present invention further includes performing a heat treatment process after forming the dielectric layer.

The method of the present invention further includes performing an ultraviolet treatment process or a curing process after forming the low dielectric layer.

The method of the present invention further includes performing the ultraviolet treatment process or the curing process after etching the low dielectric layer.

The method of the present invention further includes performing the heat treatment process and performing the ultraviolet treatment process or the curing process after forming the dielectric layer.

The method of the present invention further includes forming a nitride layer on a resultant structure including the residual low dielectric layer; and etching the nitride layer to form a nitride layer spacer on one side wall of each of the select transistor gate patterns.

### BRIEF DESCRIPTION OF THE DRAWINGS

The above and other objects, features and advantages of the present invention will become apparent from the following description of preferred embodiments given in conjunction with the accompanying drawings, in which:

FIG. 1 to FIG. 4 are sectional views illustrating a method of manufacturing a flash memory device according to an embodiment of the present invention.

### DESCRIPTION OF SPECIFIC EMBODIMENTS

Hereinafter, a preferred embodiment of the present invention is described in detail with reference to the accompanying drawings. However, the present invention is not limited to the embodiment disclosed below, and it can be embodied in various forms. The described embodiment illustrates the complete scope of the present invention to those skilled in the art.

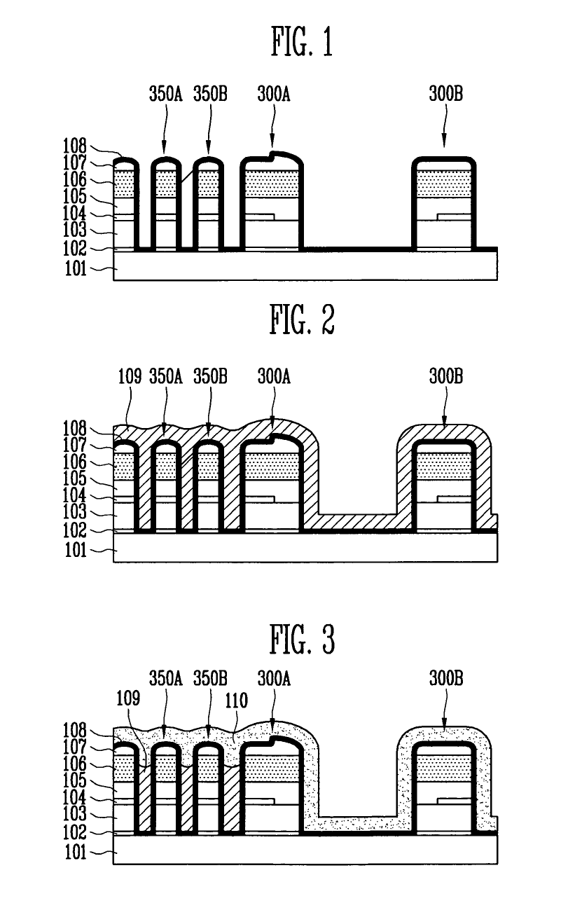

Referring to FIG. 1, an oxide layer 102, a first polysilicon layer 103, a dielectric layer 104, a second polysilicon layer 105, a conductive layer 106 and a hard mask layer 107 are formed sequentially on a semiconductor substrate 101. A gate pattern structure including cell gate patterns 350A, 350B and select transistor gate patterns 300A, 300B is then formed. A buffer oxide layer 108 is formed on the resulting gate pattern structure including the gate patterns 300A, 300B, 350A and 350B. The buffer oxide layer 108 is formed from low pressure-tetra ethyl ortho silicate (LP-TEOS) or plasma enhanced-tetra ethyl ortho silicate (PE-TEOS) and has a thickness of 50 Å to 150 Å.

Referring to FIG. 2, a low dielectric layer 109 is formed on the resultant structure from FIG. 1, including the buffer oxide layer 108 and the gate patterns 300A, 300B, 350A, and 350B. As shown in FIG. 2, the low dielectric layer 109 fills the gaps adjacent the cell gate patterns 350A, 350B (e.g., the gap between gate patterns 350A, 350B and the gap between gate patterns 350B, 300A), but it does not fill the gap between select transistor gate patterns 300A, 300B. In order to remove moisture contained in the low dielectric layer 109, a heat treatment process can be performed. An ultraviolet (UV) treatment process or a curing process also can be performed to improve the quality of the low dielectric layer 109.

In the present invention, the low dielectric layer 109 is formed by spin on dielectric (SOD) deposition or by chemical vapor deposition (CVD) using fluorinated silicate glass having a dielectric constant value of 3.2 to 3.6, hydrogen polysilozane having a dielectric constant value of approximately 3.5, hydrogen silsesquioxane having a dielectric constant value of 2.8 to 3.0, methyl silsesquioxane having a dielectric constant value of approximately 2.7, organo silicate glass having a dielectric constant value of 2.8 to 3.0, or organo aromatic polymers having a dielectric constant value of 2.6 to 2.9. The low dielectric layer has a thickness of 500 Å to 5,000 Å.

In the present invention, the heat treatment process is performed for 30 seconds to 300 seconds at a temperature of 100° C. to 150° C. under an atmosphere of any one of air, argon (Ar), and helium (He).

In the present invention, the ultraviolet (UV) treatment process is performed at a temperature of 300° C. to 400° C., with an ultraviolet electric power of 10 mW/cm² to 20 mW/cm², with a wafer-lamp distance of 50 mm to 200 mm, at a pressure of 0.1 Torr to 0.5 Torr, with a process time of 100 seconds to 500 seconds, and with an inflow gas at a rate of 10 cc/min to 100 cc/min. The inflow gas includes nitrogen (N₂), oxygen (O₂), or mixtures thereof.

In the present invention, the curing process is performed at a temperature of 300° C. to 500° C., under a steam atmosphere including water (H₂O) and oxygen (O₂), and with a process time of 30 minutes to 120 minutes.

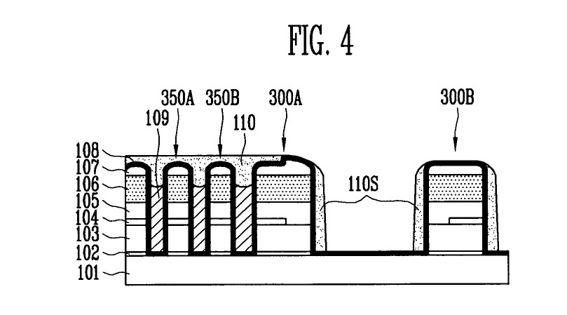

Referring to FIG. 3, the low dielectric layer 109 is etched using a wet etching process. The wet etching process removes all of the low dielectric layer 109 present in the gap between the select transistor gate patterns 300A and 300B. The wet etching process also removes the low dielectric layer 109 on the top of the gate patterns 300A, 300B, 350A and 350B. The wet etching process forms a residual low dielectric layer 109A that remains in the gaps adjacent the cell gate patterns 350A, 350B (e.g., the gap between gate patterns 350A, 350B and the gap between gate patterns 350B, 300A). Because the etching rate of the wet etching process in the narrow gaps adjacent the cell gate patterns 350A, 350B is lower than the rate in the large gap between select transistor gate patterns 300A, 300B, the residual low dielectric layer 109A remains in only the specific areas described above. A buffer oxide etchant (BOE) solution can be utilized in the wet etching process. A nitride layer 110 is formed on the resultant structure including the residual low dielectric layer 109A and the buffer oxide layer 108. The nitride layer 110 is formed by low pressure-chemical vapor deposition (LP-CVD) and has a thickness of 100 Å to 500 Å.

Additionally, the ultraviolet treatment process or the curing process can be performed a second time after etching the low dielectric layer 109 to improve the quality of the residual lower dielectric layer 109A. The conditions of the ultraviolet treatment process and the curing process are the same as those previously described.

Referring to FIG. 4, the nitride layer 110 is etched to form a nitride spacer 110S on one side wall of each of the select transistor gate patterns 300A and 300B. Upon formation of the nitride spacer 110S, a portion of the nitride layer 110 remains on an upper side of the cell gate patterns 350A and 350B. The nitride spacer 110S can be used in a self aligned contact (SAC) method in a subsequent source/drain contact forming process. In general, the spacer utilized in the SAC method is a dual spacer obtained by stacking an oxide layer and a nitride layer. However, in the present invention, since only the nitride spacer 110S is employed, the relative contact area is increased. Thus, the rate of change rate of the threshold voltage and the contact resistance in the device can be decreased.

As described above, the present invention can improve the rate of change of the threshold voltage caused by the electrical effect between the cell gate patterns by filling the gaps adjacent the gate patterns in the flash memory cell with the low dielectric material.

Also, in the present invention, the spacer formed for applying the SAC method is a single spacer (i.e., not a dual spacer) formed on one side wall of the gate pattern for the select transistor. Accordingly, the contact area is increased so that the contact resistance can be decreased.

Although the technical spirit of the present invention has been concretely described in connection with the preferred embodiment, the scope of the present invention is not limited by the specific embodiments but should be construed by the appended claims. Further, it should be understood by those skilled in the art that various changes and modifications can be made thereto without departing from the scope of the present invention.

What is claimed is:

1. A method of manufacturing a flash memory device, comprising the steps of:
(a) forming cell gate patterns and select transistor gate patterns on a semiconductor substrate, thereby forming a gate pattern structure;
(b) forming a low dielectric layer on the structure resulting from step (a); and,
(c) etching the low dielectric layer such that the low dielectric layer remains only in gaps adjacent the cell gate patterns, thereby forming a residual low dielectric layer.

2. The method of claim 1, wherein step (a) further comprises forming a buffer oxide layer on the gate pattern structure.

3. The method of claim 2, wherein the buffer oxide layer is formed from low pressure-tetra ethyl ortho silicate (LP-TEOS) or plasma enhanced-tetra ethyl ortho silicate (PE-TEOS) and has a thickness of 50 Å to 150 Å.

4. The method of claim 1, wherein the low dielectric layer is formed by spin on dielectric deposition (SOD) or chemical vapor deposition (CVD) and has a thickness of 500 Å to 5,000 Å.

5. The method of claim 1, wherein the low dielectric layer is formed from fluorinated silicate glass, hydrogen polysilozane, hydrogen silsesquioxane, methyl silsesquioxane, organo silicate glass, or organo aromatic polymers.

6. The method of claim 1, wherein step (b) further comprises performing a heat treatment process after forming the low dielectric layer.

7. The method of claim 6, wherein the heat treatment process is performed for 30 seconds to 150 seconds at a temperature of 100° C. to 150° C. under an atmosphere selected from the group consisting of air, argon (Ar), and helium (He).

8. The method of claim 1, wherein step (b) further comprises performing an ultraviolet treatment process or a curing process after forming the low dielectric layer.

9. The method of claim 8, comprising performing the ultraviolet treatment process, wherein the ultraviolet treatment process is performed at a temperature of 300° C. to 400° C., with an ultraviolet electric power of 10 mW/cm² to 20 mW/cm², with a wafer-lamp distance of 50 mm to 200 mm, at a pressure of 0.1 Torr to 0.5 Torr, with a process time of 100 seconds to 500 seconds, and with an inflow gas at a rate of 10 cc/min to 100 cc/min, the inflow gas comprising at least one of nitrogen (N₂) and oxygen (O₂).

10. The method of claim 8, comprising performing the curing process, wherein the curing process is performed at a temperature of 300° C. to 500° C., under a steam atmosphere comprising water (H₂O) and oxygen (O₂), and with a process time of 30 minutes to 120 minutes.

11. The method of claim 1, wherein step (c) further comprises performing an ultraviolet treatment process or a curing process after forming the residual low dielectric layer.

12. The method of claim 11, comprising performing the ultraviolet treatment process, wherein the ultraviolet treatment process is performed at a temperature of 300° C. to 400° C., with an ultraviolet electric power of 10 mW/cm² to 20 mW/cm², with a wafer-lamp distance of 50 mm to 200 mm, at a pressure of 0.1 Torr to 0.5 Torr, with a process time of 100 second to 500 seconds, and with an inflow gas at a rate of 10 cc/min to 100 cc/min, the inflow gas comprising at least one of nitrogen (N₂) and oxygen (O₂).

13. The method of claim 11, comprising performing the curing process, wherein the curing process is performed at a temperature of 300° C. to 500° C., under a steam atmosphere comprising water (H₂O) and oxygen (O₂), and with a process time of 30 minutes to 120 minutes.

14. The method of claim 1, wherein step (b) further comprises, after forming the dielectric layer:
performing a heat treatment process; and,
performing an ultraviolet treatment process or a curing process.

15. The method of claim 14, wherein the heat treatment process is performed for 30 seconds to 150 second at a temperature of 100° C. to 150° C. under an atmosphere selected from the group consisting of air, argon (Ar), and helium (He).

16. The method of claim 14, comprising performing the ultraviolet treatment process, wherein the ultraviolet treatment process is performed at a temperature of 300° C. to 400° C., with an ultraviolet electric power of 10 mW/cm² to 20 mW/cm², with a wafer-lamp distance of 50 mm to 200 mm, at a pressure of 0.1 Torr to 0.5 Torr, with a process time of 100 seconds to 500 seconds, and with an inflow gas at a rate of 10 cc/min to 100 cc/min, the inflow gas comprising at least one of nitrogen (N₂) and oxygen (O₂).

17. The method of claim 14, comprising performing the curing process, wherein the curing process is performed at a temperature of 300° C. to 500° C., under a steam atmosphere comprising water (H₂O) and oxygen (O₂), and with a process time of 30 minutes to 120 minutes.

18. The method of claim 1, wherein the low dielectric layer is etched using a wet etching process.

19. The method of claim 18, wherein the wet etching process uses a buffer oxide etchant (BOE) solution.

20. The method of claim 1, further comprising the steps of:
(d) forming a nitride layer on the structure resulting from step (c) including the residual low dielectric layer; and,
(e) etching the nitride layer to form a nitride layer spacer on one side wall of each of the select transistor gate patterns

21. The method of claim 20, wherein the nitride layer is formed by low pressure-chemical vapor deposition (LP-CVD) and has a thickness of 100 Å to 500 Å.
